(19) United States
(12) Patent Application Publication
(10) Pub. No.: US 2015/0357013 A1
(43) Pub. Date: Dec. 10, 2015

(54) TRACKING SCHEME FOR FLOATING BITLINE PRECHARGE

(71) Applicant: QUALCOMM Incorporated, San Diego, CA (US)

(72) Inventors: Alex Dongkyu PARK, San Diego, CA (US); Venkatasubramanian NARAYANAN, San Diego, CA (US); Ritu CHABA, San Diego, CA (US); Derek Xiaoxiang YANG, Baldwin Park, CA (US); Arun Babu PALLERLA, San Diego, CA (US)

(73) Assignee: QUALCOMM Incorporated, San Diego, CA (US)

(21) Appl. No.: 14/298,819

(22) Filed: Jun. 6, 2014

(51) Int. Cl. G11C 7/12; G11C 11/417

(52) U.S. Cl. CPC G11C 7/12; G11C 11/417

(57) ABSTRACT

A memory and a method for operating the memory are provided. The memory includes a bitline and at least one memory cell coupled to the bitline. A bitline precharge circuit is configured to precharge the bitline for a memory access and to deactivate to float the bitline in a standby state. A reference circuit is configured to charge a load circuit to a voltage in the standby state. In one example, the load circuit includes a dummy bitline having a substantially same or greater electrical characteristic of the bitline. The reference circuit includes a dummy bitline precharge circuit configured to charge the dummy bitline to the voltage in the standby state.

### BACKGROUND

1. Field

The present disclosure relates generally to electronic circuits, and more particularly, a memory with a floating bitline.

2. Background

Wireless communication technologies and mobile electronic devices (e.g., cellular phones, tablets, laptops, etc.) have grown in popularity and use over the past several years. Increasingly, mobile electronic devices have grown in complexity and now commonly include multiple processors and other resources that allow mobile device users to execute complex and power intensive software applications (e.g., web browsers, video streaming applications, etc.).

With the ever increasing demand for more processing capability in mobile devices, low power consumption has become a common design requirement for the components of the mobile electronic devices, such a processor or a memory. Various techniques are currently being employed to reduce power consumption in components of such devices. For example, a memory may be put into a sleep mode or other low power modes to reduce power consumption.

### SUMMARY

Aspects of a memory are disclosed. The memory includes a bitline and at least one memory cell coupled to the bitline. A bitline precharge circuit is configured to precharge the bitline for a memory access and to deactivate to float the bitline in a standby state.

Further aspects of a memory are disclosed. The memory includes a bitline and storage means for storing one or more values. The memory further includes bitline precharge means for precharging the bitline for a memory access and for deactivating to float the bitline in a standby state.

Aspects of a method for operating a memory are disclosed. The method includes precharging a bitline for a memory access. The the bitline is coupled to at least one memory cell. The method further includes floating the bitline in a standby state.

It is understood that other aspects of apparatus and methods will become readily apparent to those skilled in the art from the following detailed description, wherein various aspects of apparatus and methods are shown and described by way of illustration. As will be realized, these aspects may be implemented in other and different forms and its several details are capable of modification in various other respects. Accordingly, the drawings and detailed description are to be regarded as illustrative in nature and not as restrictive.

### BRIEF DESCRIPTION OF THE DRAWINGS

Various aspects of apparatus and methods will now be presented in the detailed description by way of example, and not by way of limitation, with reference to the accompanying drawings, wherein:

FIG. 1 is a block diagram illustrating an exemplary embodiment of a memory.

FIG. 2 is a block diagram illustrating an embedded application of an exemplary embodiment.

FIG. 3 is a schematic representation of an exemplary embodiment of a bitcell for an SRAM.

FIG. 4 is a functional block diagram of an exemplary embodiment of an SRAM.

FIG. 5 is a diagram illustrating the operation states of an exemplary embodiment.

FIG. 6 is the block diagram of the bitline precharge of an exemplary embodiment.

FIG. 7 is a schematic diagram of the bitline precharge of an exemplary embodiment.

FIG. 8 is a timing diagram of the bitline precharge of an exemplary embodiment.

FIG. 9 is a flowchart of the operations of an exemplary embodiment.

### DETAILED DESCRIPTION

The detailed description set forth below in connection with the appended drawings is intended as a description of various exemplary embodiments of the present invention and is not intended to represent the only embodiments in which the present invention may be practiced. The detailed description includes specific details for the purpose of providing a thorough understanding of the present invention. However, it will be apparent to those skilled in the art that the present invention may be practiced without these specific details. In some instances, well-known structures and components are shown in block diagram form in order to avoid obscuring the concepts of the present invention. Acronyms and other descriptive terminology may be used merely for convenience and clarity and are not intended to limit the scope of the invention.

Various apparatus and methods presented throughout this disclosure may be implemented in various forms of hardware. By way of example, any of these apparatus or methods, either alone or in combination, may be implemented as an integrated circuit, or as part of an integrated circuit. The integrated circuit may be an end product, such as a microprocessor, a digital signal processor (DSP), an application specific integrated circuit (ASIC), programmable logic, or any other suitable integrated circuit. Alternatively, the integrated circuit may be integrated with other chips, discrete circuit elements, and/or other components as part of either an intermediate product, such as a motherboard, or an end product. The end product can be any suitable product that includes integrated circuits, including by way of example, a cellular phone, personal digital assistant (PDA), laptop computer, a desktop computer (PC), a computer peripheral device, a multimedia device, a video device, an audio device, a global positioning system (GPS), a wireless sensor, or any other suitable device.

The word “exemplary” is used herein to mean serving as an example, instance, or illustration. Any embodiment described herein as “exemplary” is not necessarily to be construed as preferred or advantageous over other embodiments. Likewise, the term “embodiment” of an apparatus or method does not require that all embodiments of the invention include the described components, structure, features, functionality, processes, advantages, benefits, or modes of operation.

The terms “connected,” “coupled,” or any variant thereof, mean any connection or coupling, either direct or indirect, between two or more elements, and can encompass the presence of one or more intermediate elements between two elements that are “connected” or “coupled” together. The coupling or connection between the elements can be physical, logical, or a combination thereof As used herein, two elements can be considered to be “connected” or “coupled” together by the use of one or more wires, cables and/or printed electrical connections, as well as by the use of electromagnetic energy, such as electromagnetic energy having wavelengths in the radio frequency region, the microwave region and the optical (both visible and invisible) region, as several non-limiting and non-exhaustive examples.

Any reference to an element herein using a designation such as “first,” “second,” and so forth does not generally limit the quantity or order of those elements. Rather, these designations are used herein as a convenient method of distinguishing between two or more elements or instances of an element. Thus, a reference to first and second elements does not mean that only two elements can be employed, or that the first element must precede the second element.

As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of the stated features, integers, steps, operations, elements, and/or components, but do not preclude the presence or addition of one or more other features, integers, steps, operations, elements, components, and/or groups thereof.

Various aspects of a memory on an integrated circuit (IC) having a novel sleep mode will now be presented. Such IC may be, for example, a system-on-chip (SOC) processor for a communication apparatus (such as a mobile phone). However, as those skilled in the art will readily appreciate, such aspects may be extended to other circuit configurations. Accordingly, all references to a specific application for a memory are intended only to illustrate exemplary aspects of the memory with the understanding that such aspects may have a wide differential of applications.

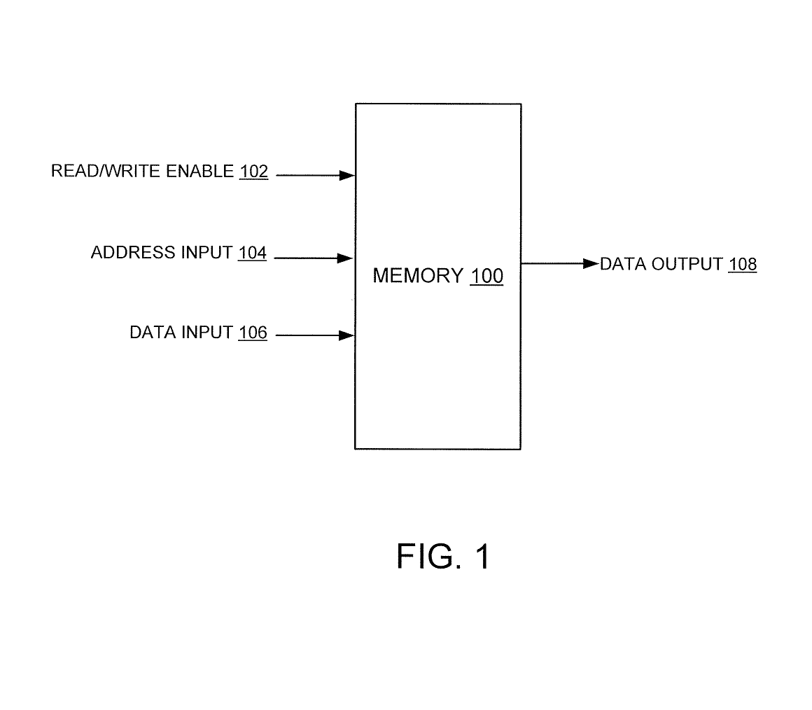

FIG. 1 is a block diagram illustrating an exemplary embodiment of a memory. The memory 100 provides a medium for peripheral circuits to write and read program instructions and data. As used hereinafter, the term “data” will be understood to include program instructions, data, and any other information that may be stored in the memory 100. The memory 100 includes a read/write enable 102 for controlling the read/write operation of the memory 100. The memory 100 also includes an address input 104, a data input 106 for writing data to the memory 100 at the specified address, and a data output 108 for reading data from the memory 100 at the specified address. When writing data to the memory 100, a peripheral circuit sets the read/write enable to the write mode and sends to the memory 100 the address along with the data to be written to the memory 102 at that address. When reading data from the memory 100, the peripheral circuit sets the read/write enable to the read mode and sends the address to the memory 100. In response, the memory 100 sends data at that address to the peripheral circuit.

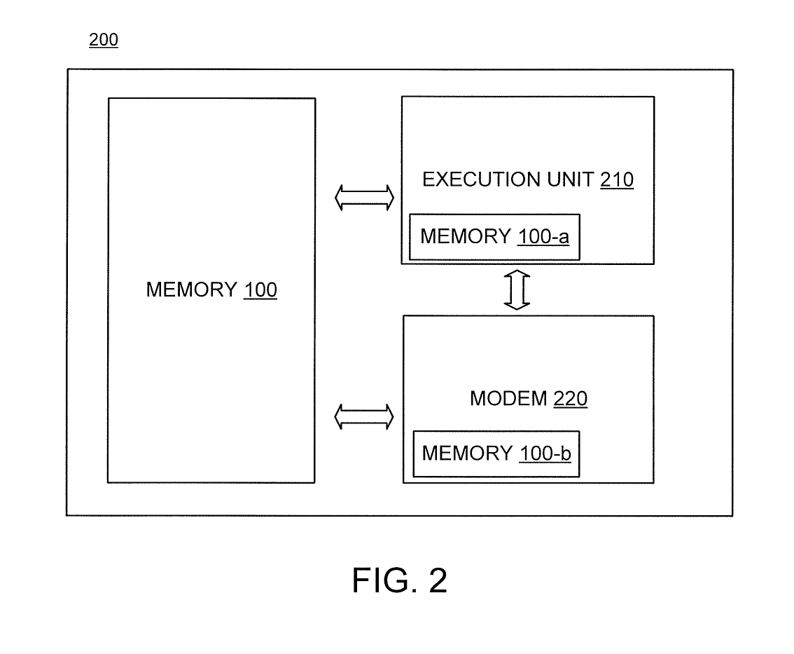

FIG. 2 is a block diagram illustrating an embedded application of an exemplary embodiment. The memory 100 may be a discrete memory on its own substrate or be utilized for embedded applications. FIG. 2 illustrates an example of a system-on-chip processor 200. The processor 200 may be a processor for a cell phone and includes an execution unit 210 and a modem 220 (which handles the communication functions of the cell phone). The memory 100 may function as a cache memory for the processor 200 or be used for any storage needs. The memory 100 may be formed on a same substrate as the execution unit 210 and the modem 220. The memory 100 may also be on its own substrate and packaged with the processor 200 by a substrate-on-substrate assembly. Moreover, a memory 100-a may be integrated as part of the execution unit 210 and may function as, e.g., a register file for the execution unit 210. A memory 100-b may likewise be integrated as part of the modem 220.

The memory 100 may be any suitable storage medium, such as, by way of example, a static random access memory (SRAM). SRAM is volatile memory that requires power to retain data. However, as those skilled in the art will readily appreciate, the memory 102 is not necessarily limited to SRAM. Accordingly, any reference to SRAM is intended only to illustrate various concepts, with the understanding that such concepts may be extended to other memories.

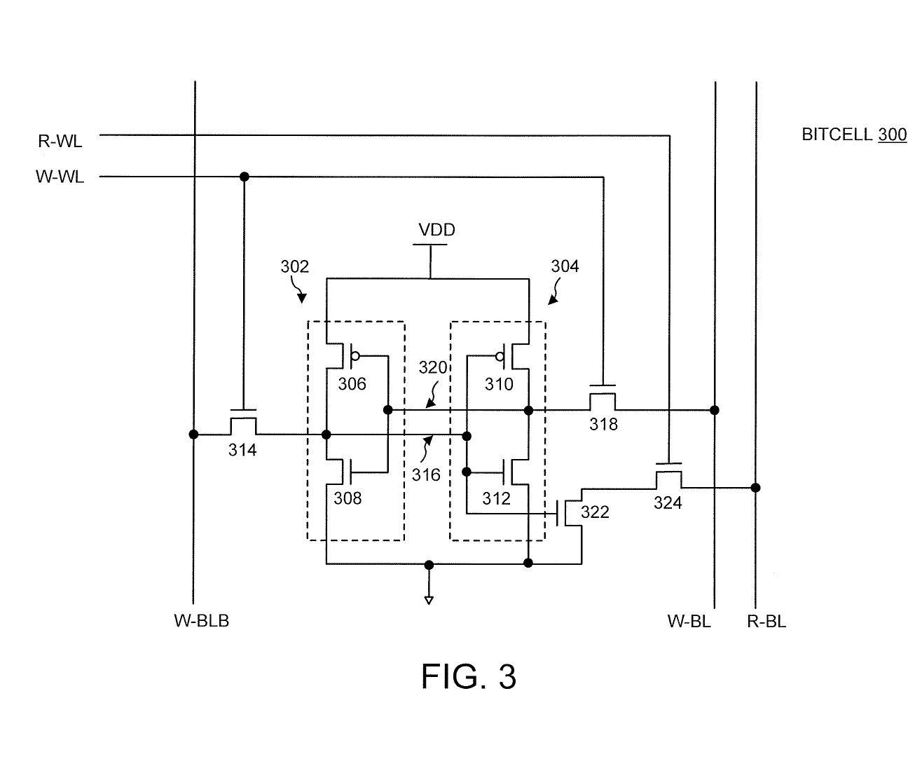

SRAM includes an array of storage elements know as “bitcells” or memory cells. Each bitcell is configured to store one bit of data. FIG. 3 is a schematic representation of an exemplary embodiment of a bitcell for an SRAM. The bitcell is implemented with an eight-transistor (8T) configuration. However, as those skilled in the art will readily appreciate, the bitcell may be implemented with a four-transistor (4T), six-transistor (6T), ten-transistor (10T) configuration, or any other suitable transistor configuration.

The bitcell (or memory cell) 300 is shown with two inverters 302, 304. The first inverter 302 comprises a P-channel transistor 306 and an N-channel transistor 308. The second inverter 304 comprises a P-channel transistor 310 and an N-channel transistor 312. The first and second inverters 302, 304 are interconnected to form a cross-coupled latch. A first N-channel write access transistor 314 couples the output 316 from the first inverter 302 to a first local write bitline W-BLB and a second N-channel write access transistor 318 couples the output 320 from the second inverter 304 to a second local write bitline W-BL. The gates of the N-channel write access transistors 314, 318 are coupled to a write wordline W-WL. The output 316 from the first inverter 302 is also coupled to the gate of an N-channel transistor 322. An N-channel read access transistor 324 couples the output from the N-channel transistor 322 to a local read bitline R-BL. The gate of the N-channel read access transistor 324 is coupled to a read wordline R-WL.

The write operation is initiated by setting the local write bitlines W-BLB, W-BL to the value to be written to bitcell 300 and then asserting the write wordline W-WL. By way of example, a logic level 1 may be written to the bitcell 300 by setting the first local write bitline BLB to a logic level 0 and the second local write bitline BL to a logic level 1. The logic level 0 at the first local write bitline W-BLB is applied to the input of the second inverter 304 through the write access transistor 314, which in turn forces the output 320 of the second inverter 304 to a logic level 1. The output 320 of the second inverter 304 is applied to the input of the first inverter 302, which in turn forces the output 316 of the first inverter 302 to a logic level 0. A logic level 0 may be written to the bitcell 300 by inverting the values of the local write bitlines W-BLB, W-BL. The local write bitline drivers (not shown) are designed to be much stronger than the transistors in the bitcell 300 so that they can override the previous state of the cross-coupled inverters 302, 304.

The read operation is initiated by precharging the local read bitline R-BL to a logic level 1 and then asserting the read wordline R-WL. With the read wordline asserted, the output from the N-channel transistor 322 is transferred to the local read bitline R-BL through the read access transistor 324. By way of example, if the value stored at the output 320 of the second inverter 304 is a logic level 0, the output 316 from the first inverter 302 forces the N-channel transistor 322 on, which in turn causes the local read bitline R-BL to discharge to a logic level 0 through the read access transistor 324 and the N-channel transistor 322. If the value stored at the output 320 of the second inverter 304 is a logic level 1, the output 316 from the first inverter 302 forces the N-channel transistor 322 off As a result, the local read bitline R-BL remains charged to a logic level 1.

When the SRAM is in a standby state, the write wordline W-WL and read wordline R-WL are set to a logic level 0. The logic level 0 causes the write access transistors 314, 318 and the read access transistor 324 to disconnect the local write and read bitlines W-BL, W-BLB, R-BL from the two inverters 302, 304. The cross-coupling between the two inverters 302, 304 maintains the state of the output as long as power (e.g. VDD) is applied to the bitcell 300.

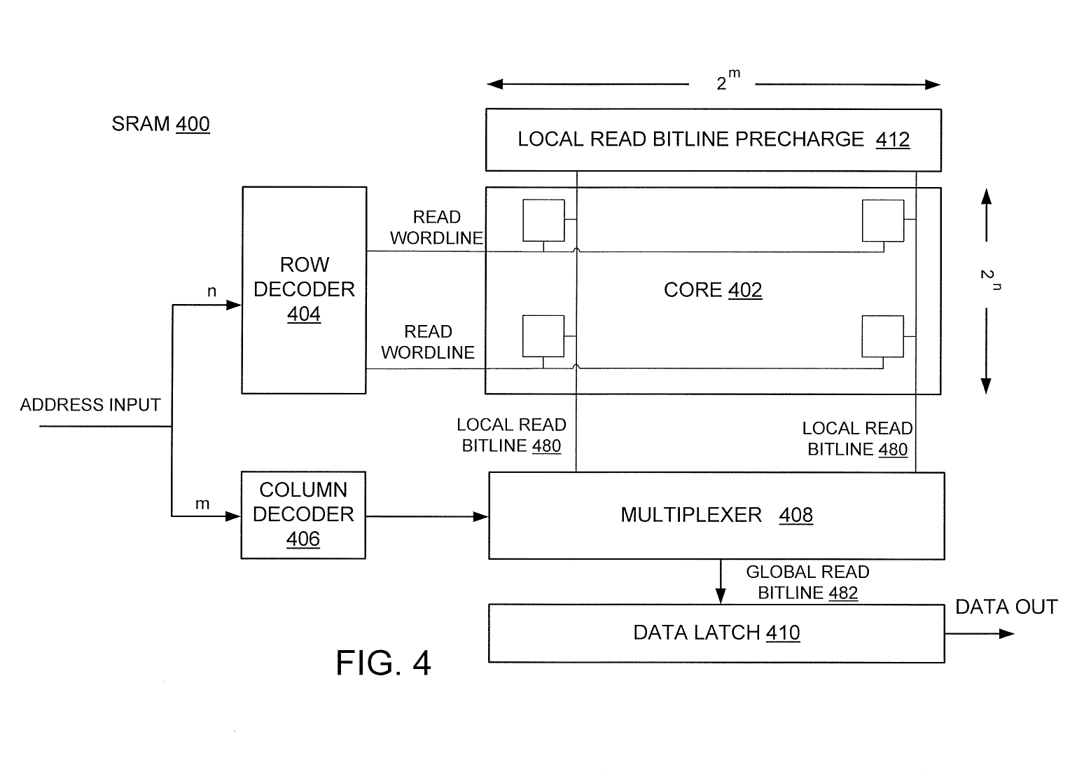

FIG. 4 is a functional block diagram of an exemplary embodiment of an SRAM. Various aspects of an SRAM will now be presented in the context of a read operation. Accordingly, for clarity of presentation, only the connections for the read operation are shown. Those skilled in the art will readily appreciate that additional connections are required to support the write operation.

The SRAM 400 includes a memory core 402 with supporting circuitry to decode addresses and perform read and write operations. The memory core 402 is comprised of bitcells arranged to share connections in horizontal rows and vertical columns. Specifically, each horizontal row of bitcells shares a read wordline and each vertical column of bitcells shares a local read bitline. The size of the memory core 402 (i.e., the number of bitcells) may vary depending on a variety of factors including the specific application, the speed requirements, the layout and testing requirements, and the overall design constraints imposed on the system. Typically, the memory core 402 will contain thousands or millions of bitcells.

In the exemplary embodiment of the SRAM shown in FIG, 4, the memory core 402 is made up of (2ⁿ×2^{m}) bitcells arranged in 2ⁿ horizontal rows and 2^{m} vertical columns. A peripheral device (not shown) may randomly access any bitcell in the memory core 402 using an address that is (n+m) bits wide. In this example, n-bits of the address are provided to the input of a row decoder 404 and m-bits of the address are provided to the input of a column decoder 406. The SRAM 400 is placed into a read mode by the read/write enable signal (not shown). The read/write enable signal causes, among other things, the precharging of the local read bitlines by the local read bitline precharge 412.

The row decoder 404 converts the n-bit address into 2ⁿ read wordline outputs. A different read wordline is asserted by the row decoder 404 for each different n-bit row address. As a result, each of the 2^{m} bitcells in the horizontal row with the asserted read wordline is connected to one of the 2^{m} local read bitlines 480 through its access transistor as described above in connection with FIG. 3. The 2^{m} local read bitlines 480 are used to transmit the bits stored by the m bitcells to a multiplexer 408 that selects one or more bits from the 2^{m} bits transmitted on the local read bitlines 480. The number of bits that are selected by the multiplexer is based on the width of the SRAM output. By way of example, the multiplexer may select 64 of the 2^{m} bits to support an SRAM having a 64-bit output. In the described exemplary embodiment, the multiplexer selects one of the 2^{m} bits. The selected bit may be referred to as a global read bitline 482.

The global read bitline 482 from the multiplexer 408 is provided to a data latch 410 for further processing (e.g., latching) before being output to a peripheral circuit (not shown). In one example, the data latch 410 provides the data from the global read bitline 482 to the execution unit 210 or the modem 220.

A memory may be put into a sleep mode or other low power modes to reduce power consumption. An example of a sleep mode electrically decouples all parts of the memory from all power supplies. This sleep mode is advantageous in that the memory consumes no power in such mode. However, activating the memory for a memory access from the sleep mode may require substantial delays (e.g., additional wait delays may need to be added intentionally after exiting the sleep mode). Moreover, no power-saving is achieved when the memory is activated but not in a memory access (e.g., the memory is in a standby state).

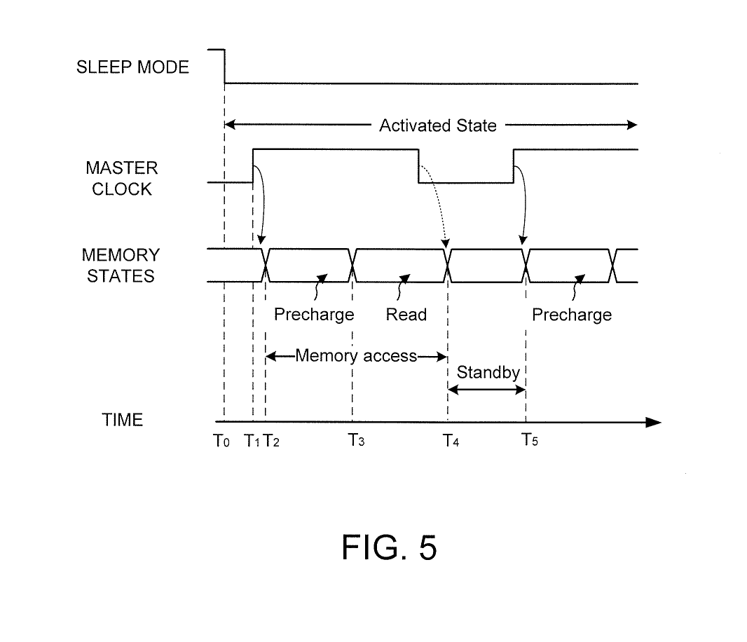

FIG. 5 is a diagram illustrating the operation states of an exemplary embodiment (e.g., SRAM 400). For illustrative purpose, the local read bitline states in a read memory access are provided, but the scope of the current disclosure is not limited thereto. At T₀, the SLEEP MODE signal deactivates (goes to a low state), and the exemplary embodiment memory enters into an activated state. That is, the memory is in a memory access cycle or is in a standby state ready for the memory access. A memory entering and exiting a low power mode (such as the sleep mode) based on a SLEEP MODE signal is well known in the art, and therefore, the details of such scheme are not shown here.

The memory access is initiated by the MASTER CLOCK signal. At T₁, the

MASTER CLOCK signal activates (goes to a high state) and initiates a read memory access (T₂-T₄). In the read memory access, the memory first precharges the local read bitline 480 in the precharge period (T₂-T₃). When the precharging completes, the memory performs the read operation (T₃-T₄). When the memory access ends at T₄, the memory enters into the standby state (T₄-T₅) until the next memory access starts at T₅. In one example, the memory enters the standby state when the memory access ends. In another example, the memory may optionally enter the standby state in response to the MASTER CLOCK signal being deactivated (a low state).

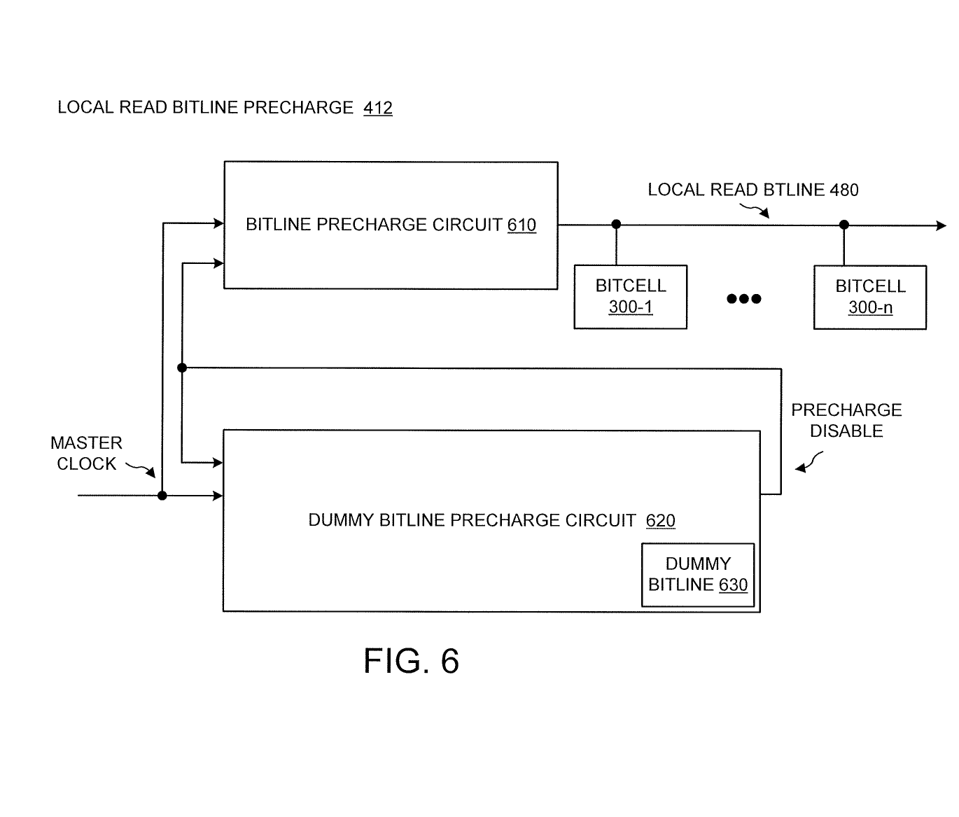

FIG. 6 is the block diagram of the bitline precharge (e.g., the local read bitline precharge 412) of an exemplary embodiment (e.g., SRAM 400). The local read bitline precharge 412 includes a bitline precharge circuit 610 that precharges or pulls the local read bitline 480 to a high level in a precharge period (e.g., T₂-T₃) for a memory access. The high level may be, e.g., the supply voltage or VDD level, and the bitline precharge circuit 610 may precharge the local read bitline 480 to VDD for the memory access. The local read bitline 480 is coupled to n memory cells (bitcells 300-1-300-n). In the read operation (T₃-T₄), the local read bitline 480 may be selectively pulled down based on a value stored in one of the n memory cells coupled to the local read bitline 480. As described with FIGS. 3 and 4, one of the n read wordlines R-WL activates and couples the associated bitcell to the local read bitline 480 in a read operation.

The local read bitline precharge 412 further includes a dummy bitline precharge circuit 620. In one example, the dummy bitline precharge circuit 620 is a reference circuit that determines a timing of precharging the local read bitline 480. The dummy bitline precharge circuit 620 includes a dummy bitline 630 and is configured to charge the dummy bitline 630 in the precharge period. A dummy bitline may be a load circuit (e.g., capacitors and resistors) that emulates at least one electrical characteristic of the local read bitline 480 (e.g., capacitance, resistance, or inductance). Thus, the dummy bitline 630 has at least one electrical characteristic that is substantially the same as that of the local read bitline 480. In one example, the dummy bitline 630 may be a conductive line of the same material as the local read bitline 480, and placed next to the local read bitline 480. The dummy bitline 630 may further include n dummy bitcells (cells that emulate the loading of the bitcell 300) coupled thereto. In another example, the dummy bitline 630 may include capacitors, resistors, and/or inductors that are/is substantially the same or the same as the capacitance, resistance, and/or inductance of the local read bitline 480. In another example, the capacitance, resistance, and/or inductance of the dummy bitline 630 is designed to be greater than that of the local read bitline 480, such that the charging of the dummy bitline 630 is slower than the charging of the local read bitline 480.

The dummy bitline precharge circuit 620 charges or pulls up the dummy bitline 630 to a high level in the precharge period (e.g., T₂-T₃). In operation, both the bitline precharge circuit 610 and the dummy bitline precharge circuit 620 are enabled by the MASTER CLOCK signal (which initiates the memory access) for charging the local read bitline 480 and the dummy bitline 630, respectively. Upon charging the dummy bitline 630 to a predetermined high level (e.g., a level near VDD), the dummy bitline precharge circuit 620 activates the PRECHARGE DISABLE signal (goes to a high state). The PRECHARGE DISABLE signal is provided to both the bitline precharge circuit 610 and the dummy bitline precharge circuit 620. The PRECHARGE DISABLE signal, when activated, deactivates both the bitline precharge circuit 610 from precharging the local read bitline 480 and the dummy bitline precharge circuit 620 from charging the dummy bitline 630. Thus, the precharge period is terminated based on a charging time of the dummy bitline 630. The period for precharging the local read bitline 480 is thus based on a time to charge the dummy bitline 630 (e.g., the time to charge the dummy bitline 630 to a predetermined voltage level).

Upon the termination of the period for precharging the local read bitline 480, the read operation may start. A bitcell or memory cell (one of 300-1 to 300-n) coupled to the local read bitline 480 may selectively pull down the local read bitline 480. First, the read wordline R-WL goes high to select a bitcell or memory cell (one of 300-1 to 300-n). The selected bitcell or memory cell may selectively output a value onto the local read bitline 480 based on its stored value. As illustrates in FIG. 3, a bitcell 300 may include an N-channel transistor 322 which functions as a pull-down circuit in the read operation and selectively pulls down the local read bitline 480 based on the stored value of the storage element.

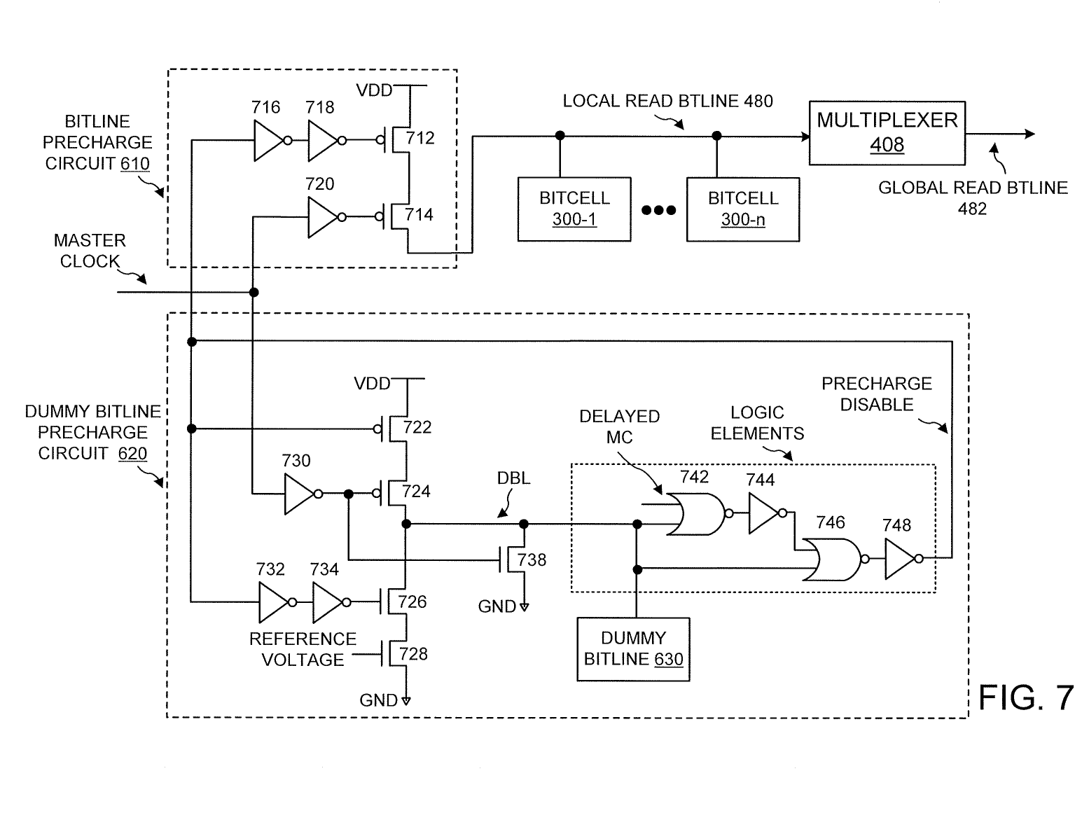

FIG. 7 is a schematic diagram of the bitline precharge of an exemplary embodiment (e.g., SRAM 400). The bitline precharge circuit 610 includes P-type metal-oxide-semiconductor (PMOS or P-channel) transistors 712 and 714 connected in series for precharging or pulling up the local read bitline 480 in the precharge period. The P-channel transistor 712 is coupled to the supply voltage VDD and is controlled by the PRECHARGE DISABLE signal (buffered by the inverters 716 and 718). The P-channel transistor 714 is coupled to the local read bitline 480 and controlled by the MASTER CLOCK signal (inverted by the inverter 720). In the standby state, both the PRECHARGE DISABLE signal and the MASTER CLOCK signal are deactivated (in the low state). Thus, the P-channel transistor 712 is on, and the P-channel transistor 714 is off in the standby state. The charging of the local read bitline 480 is thus disabled by the P-channel transistor 714, and the local read bitline 480 floats in the standby state. Accordingly, the local read bitline 480 is not electrically coupled to any supply voltage (e.g., VDD or the ground GND), and the bitline precharge circuit 610 draws no power in the standby state.

To initiate a memory access, the MASTER CLOCK signal activates and starts a precharge period. The P-channel transistor 714 is turned on by the activation of the MASTER CLOCK signal, and the local read bitline 480 is precharged or pulled up to the supply voltage VDD by the P-channel transistor 712 and the P-channel transistor 714. The precharge period ends when the PRECHARGE DISABLE signal is activated, which turns off the P-channel transistor 712.

The dummy bitline precharge circuit 620 includes P-channel transistors 722 and 724 connected in series for charging or pulling up the dummy bitline 630 in the precharge period. The P-channel transistor 722 is coupled to the supply voltage VDD and is controlled by the PRECHARGE DISABLE signal. The P-channel transistor 724 is coupled to the dummy bitline 630 at the node DBL and is controlled by the MASTER CLOCK signal (inverted by the inverter 730). In the standby state, both the PRECHARGE DISABLE signal and the MASTER CLOCK signal are deactivated. Thus, the P-channel transistor 722 is on, and the P-channel transistor 724 is off. The charging of the dummy bitline 630 is thus disabled by the P-channel transistor 724 in the standby state.

The dummy bitline precharge circuit 620 further includes the N-channel transistor 738 coupled to the node DBL (which is connected to the dummy bitline 630) and GND. The N-channel transistor 738 is controlled by the MASTER CLOCK signal via the inverter 730. In the standby state, the MASTER CLOCK signal is deactivated, and the N-channel transistor 738 is turned on. Upon turning on the N-channel transistor 738, the node DBL is discharged (e.g., charge to ground or GND) in the standby state.

The dummy bitline precharge circuit 620 further includes N-channel transistors 726 and 728 connected in series for slowly discharging the dummy bitline 630 in the memory access. The N-channel transistor 728 is coupled to ground (GND) and is controlled by the reference voltage. The reference voltage keeps the N-channel transistor 728 in an ON state and controls the current flowing through the N-channel transistor 728. The N-channel transistor 726 is coupled to the dummy bitline 630 at the node DBL and is controlled by the PRECHARGE DISABLE signal (buffered by the inverters 732 and 734). In the standby state, the PRECHARGE DISABLE signal is deactivated, and the N-channel transistor 726 is off.

The dummy bitline precharge circuit 620 further includes logic elements for generating the PRECHARGE DISABLE signal. The logic elements include NOR gates 742 and 746 and inverters 744 and 748 and receive a DELAY MC signal and the node DBL as inputs. The DELAY MC signal is a delayed version of the MASTER CLOCK signal and generally has the same state as the MASTER CLOCK signal. In the standby state, the node DBL is discharged to GND, and the DELAY MC signal, following the MASTER CLOCK signal, is likewise deactivated (goes to the low state). Thus, the PRECHARGE DISABLE signal outputted from the logic elements is deactivated in the standby state.

To initiate a memory access, the MASTER CLOCK signal activates and starts the precharge period. The P-channel transistor 724 is turned on by the activation of the MASTER CLOCK signal, and the dummy bitline 630 at node DBL is charged or pulled up to a predetermined voltage by the P-channel transistor 722 and the P-channel transistor 724. The predetermined voltage is one that changes the state of the NOR gates 742 and 746 and leads the logic elements to activate the PRECHARGE DISABLE signal. By adjusting the predetermined voltage, the precharging of the dummy bitline 630 may be configured to be slower than the precharging of the local read bitline 480 to ensure that the PRECHARGE DISABLE signal is activated after the precharging of the local read bitline 480 (e.g., the local read bitline 480 is pulled up to the VDD level).

Upon the activation of the PRECHARGE DISABLE signal, the precharge period is terminated in the following manner. The activation of the PRECHARGE DISABLE signal turns off the P-channel transistor 722 and ends the charging of the node DBL (dummy bitline 630). The activation of the PRECHARGE DISABLE signal also turns on the N-channel transistor 726 and starts to discharge the node DBL (dummy bitline 630). After the PRECHARGE DISABLE signal is activated, the DELAY MC signal (following the MASTER CLOCK signal) also activates (goes to a high level). The activation of the DELAY MC signal keeps the PRECHARGE DISABLE signal activated (at the high state) while the node DBL is being discharged by the N-channel transistors 726 and 728.

Moreover, the activation of the PRECHARGE DISABLE signal turns off the P-channel transistor 712 (via the inverters 716 and 718) and ends the precharging of the local read bitline 480. Thus, the precharge period is based on a time to charge the dummy bitline 630 (e.g., to a predetermined voltage level). The activation of the PRECHARGE DISABLE signal thus deactivates the bitline precharge circuit 610 and floats the local read bitline 480 in the standby state (e.g., after the read operation ends).

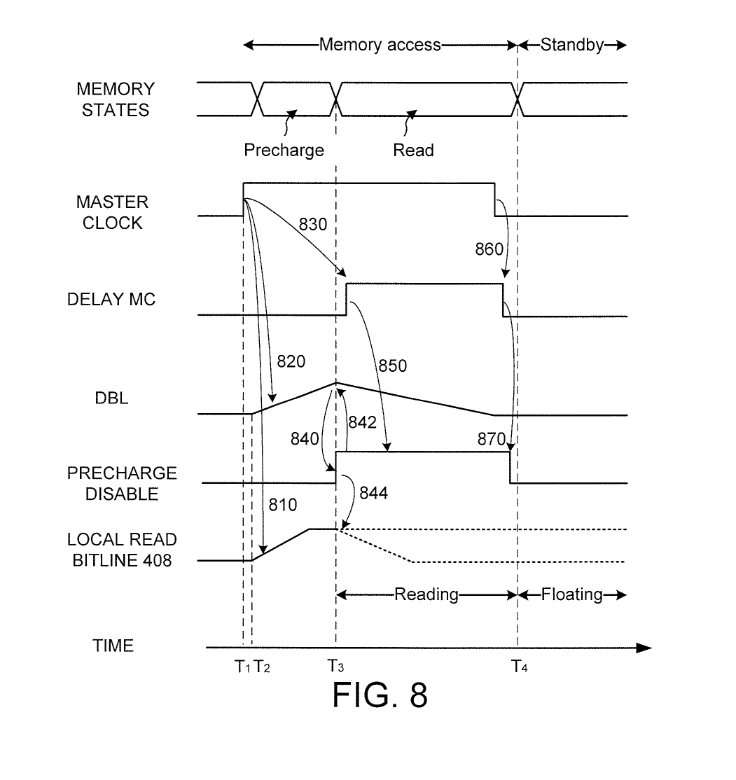

FIG. 8 is a timing diagram of the bitline precharge of an exemplary embodiment (e.g., SRAM 400). FIG. 8 illustrates various waveforms as described with FIGS. 5-7. At T₁, the MASTER CLOCK signal activates and initiates a read memory access (T₂-T₄). In the read memory access, the memory first precharges the local read bitline 480 in the precharge period (T₂-T₃) to, e.g., VDD. The activation of the MASTER CLOCK signal starts the precharging of the local read bitline 480 (at 810) and the charging of the dummy bitline 630 (at 820). The DELAY MC signal follows the MASTER CLOCK and activates (at 830), but with a delay.

At T₃, upon charging the dummy bitline 630 at node DBL to a predetermined level, the PRECHARGE DISABLE signal activates (at 840). The activation of the PRECHARGE DISABLE signal deactivates the bitline precharge circuit 610 and floats the local read bitline 480 (at 844). The activation of the PRECHARGE DISABLE signal also deactivates the dummy bitline precharge circuit 620 and initiates the discharging of the dummy bitline 630 at node DBL by the dummy bitline precharge circuit 620 (at 842). The activated DELAY MC signal (high state) holds the PRECHARGE DISABLE signal in the activated state (by the operation of the logic elements of the dummy bitline precharge circuit 620). During the precharge period (T₂-T₃), the local read bitline 480 is precharged based on a charging time of the dummy bitline 630.

Accordingly, the charging of the dummy bitline 630 and the local read bitline 480 ends at T₃, and the read operation (T₃-T₄) may start. In the read operation, the local read bitline 480 may be pulled down based on the valued stored in the selected bitcell or memory call 300. Subsequently, the MASTER CLOCK signal may deactivate. The DELAY MC may follow and deactivate (goes to a low state)(at 860). The deactivated DELAY MC causes the PRECHARGE DISABLE signal to deactivate (by the operation of the logic elements of the dummy bitline precharge circuit 620).

When the memory access (the read operation) ends at T₄, the memory enters into the standby state. In the standby state, the bitline precharge circuit 610 is deactivated and the local read bitline 480 is floating. The dummy bitline precharge circuit 620 charges the dummy bitline 630 to GND in the standby state. The charging of the dummy bitline 630 to GND serves as a reference for precharging the local read bitline 480 in the subsequent memory access. As the local read bitline 480 floats in the standby state, the actual voltage level of the local read bitline 480 is unknown when the next memory access starts. By charging the dummy bitline 630 in the standby state to a known state (e.g., to GND), the memory may ascertain the needed precharge period by charging the dummy bitline 630 from the known GND state to the predetermined voltage to activate the PRECHARGE DISABLE signal.

As described above, the bitcell or memory cell 300 provides the means for storing one or more values. A bitline precharge circuit 610 provides the means for precharging the local read bitline 480 for a memory access and the means for deactivating to float the local read bitline 480 in a standby state. The dummy bitline precharge circuit 620 provides the means for charging a load circuit (e.g., the dummy bitline 630) to GND in the standby state. The dummy bitline precharge circuit 620 also provides the means for charging a load circuit (e.g., the dummy bitline 630) to the predetermined voltage to activate the PRECHARGE DISABLE signal in a precharge period. The bitline precharge circuit 610 further provides the means for precharging the local read bitline 480 to VDD for the memory access in a time period based on the precharge period.

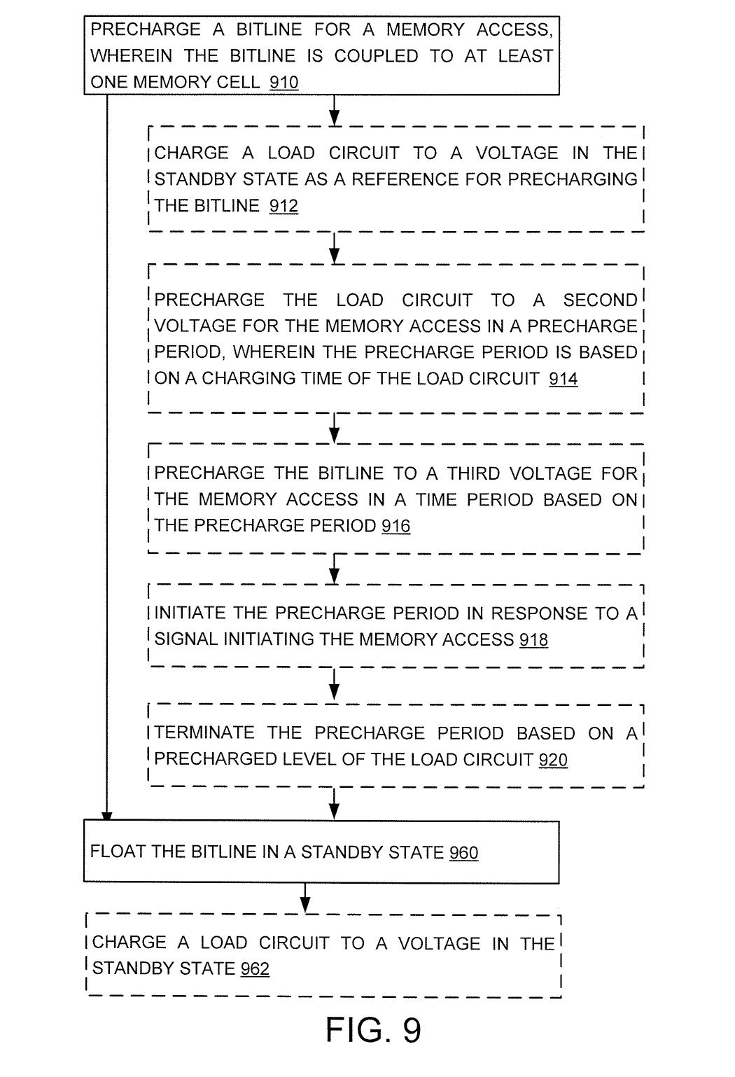

FIG. 9 is a flowchart of the operations of an exemplary embodiment (e.g., SRAM 400). The steps drawn in dotted lines may be optional. At 910, the bitline (e.g., the local read bitline 480) is precharged for a memory access (See, e.g., FIG. 8 at 810). The bitline is coupled to at least one memory cell (e.g., memory cell 300). The precharge may be performed by the bitline precharge circuit 610. For example, the bitline precharge circuit 610 includes P-type metal-oxide-semiconductor (PMOS or P-channel) transistors 712 and 714 connected in series for precharging or pulling up the local read bitline 480 in the precharge period. The P-channel transistor 712 is coupled to the supply voltage VDD and is controlled by the PRECHARGE DISABLE signal (buffered by the inverters 716 and 718). The P-channel transistor 714 is coupled to the local read bitline 480 and controlled by the MASTER CLOCK signal (inverted by the inverter 720). To initiate a memory access, the MASTER CLOCK signal activates and starts a precharge period. The P-channel transistor 714 is turned on by the activation of the MASTER CLOCK signal, and the local read bitline 480 is precharged or pulled up to the supply voltage VDD by the P-channel transistor 712 and the P-channel transistor 714. The precharge period ends when the PRECHARGE DISABLE signal is activated, which turns off the P-channel transistor 712.

At 962, the load circuit (e.g., the dummy bitline 630) is charged to a voltage (e.g., GND) in the standby state (see, e.g., FIG. 8 at T₃). For example, the dummy bitline precharge circuit 620 includes P-channel transistors 722 and 724 connected in series for charging or pulling up the dummy bitline 630 in the precharge period. The P-channel transistor 722 is coupled to the supply voltage VDD and is controlled by the PRECHARGE DISABLE signal. The P-channel transistor 724 is coupled to the dummy bitline 630 at the node DBL and is controlled by the MASTER CLOCK signal (inverted by the inverter 730). In the standby state, both the PRECHARGE DISABLE signal and the MASTER CLOCK signal are deactivated. Thus, the P-channel transistor 722 is on, and the P-channel transistor 724 is off The charging of the dummy bitline 630 is thus disabled by the P-channel transistor 724 in the standby state. The dummy bitline precharge circuit 620 further includes the N-channel transistor 738 coupled to the node DBL (which is connected to the dummy bitline 630) and GND. The N-channel transistor 738 is controlled by the MASTER CLOCK signal via the inverter 730. In the standby state, the MASTER CLOCK signal is deactivated, and the N-channel transistor 738 is turned on. Upon turning on the N-channel transistor 738, the node DBL is discharged (e.g., charge to ground or GND) in the standby state.

At 912, the load circuit is charged to a voltage (e.g., GND) in the standby state as a reference for precharging the bitline (see, e.g., FIG. 8 at 842). For example, to initiate a memory access, the MASTER CLOCK signal activates and starts the precharge period. The P-channel transistor 724 is turned on by the activation of the MASTER CLOCK signal, and the dummy bitline 630 at node DBL is charged or pulled up to a predetermined voltage by the P-channel transistor 722 and the P-channel transistor 724. The predetermined voltage is one that changes the state of the NOR gates 742 and 746 and leads the logic elements to activate the PRECHARGE DISABLE signal. By adjusting the predetermined voltage, the precharging of the dummy bitline 630 may be configured to be slower than the precharging of the local read bitline 480 to ensure that the PRECHARGE DISABLE signal is activated after the precharging of the local read bitline 480 (e.g., the local read bitline 480 is pulled up to the VDD level). The activation of the PRECHARGE DISABLE signal turns off the P-channel transistor 712 (via the inverters 716 and 718) and ends the precharging of the local read bitline 480. Thus, the precharge period is based on a time to charge the dummy bitline 630 (e.g., to a predetermined voltage level). The activation of the PRECHARGE DISABLE signal thus deactivates the bitline precharge circuit 610 and floats the local read bitline 480 in the standby state (e.g., after the read operation ends). The charging of the dummy bitline 630 to GND serves as a reference for precharging the local read bitline 480 in the subsequent memory access. As the local read bitline 480 floats in standby state, the actual voltage level of the local read bitline 480 is unknown when the next memory access starts. By charging the dummy bitline 630 in the standby state to a known state (e.g., to GND), the memory may ascertain the needed precharge period by charging the dummy bitline 630 from the known GND state to the predetermined voltage to activate the PRECHARGE DISABLE signal.

At 914, the load circuit is precharged to a second voltage (e.g., a predetermined voltage) for the memory access in a precharge period (see, e.g., FIG. 8 at 820; T₂-T₃). The precharge period is based on a charging time of the load circuit. For example, the dummy bitline precharge circuit 620 includes P-channel transistors 722 and 724 connected in series for charging or pulling up the dummy bitline 630 in the precharge period (FIG. 7). To initiate a memory access, the MASTER CLOCK signal activates and starts the precharge period. The P-channel transistor 724 is turned on by the activation of the MASTER CLOCK signal, and the dummy bitline 630 at node DBL is charged or pulled up to a predetermined voltage by the P-channel transistor 722 and the P-channel transistor 724. The predetermined voltage is one that changes the state of the NOR gates 742 and 746 and leads the logic elements to activate the PRECHARGE DISABLE signal. By adjusting the predetermined voltage, the precharging of the dummy bitline 630 may be configured to be slower than the precharging of the local read bitline 480 to ensure that the PRECHARGE DISABLE signal is activated after the precharging of the local read bitline 480 (e.g., the local read bitline 480 is pulled up to the VDD level).

At 916, the bitline is precharged to a third voltage (e.g., VDD) for the memory access in a time period based on the precharge period (see, e.g., FIG. 8 at 844). For example, the bitline precharge circuit 610 includes P-type metal-oxide-semiconductor (PMOS or P-channel) transistors 712 and 714 connected in series for precharging or pulling up the local read bitline 480 in the precharge period. The P-channel transistor 712 is coupled to the supply voltage VDD and is controlled by the PRECHARGE DISABLE signal (buffered by the inverters 716 and 718). The P-channel transistor 714 is coupled to the local read bitline 480 and controlled by the MASTER CLOCK signal (inverted by the inverter 720). To initiate a memory access, the MASTER CLOCK signal activates and starts a precharge period. The P-channel transistor 714 is turned on by the activation of the MASTER CLOCK signal, and the local read bitline 480 is precharged or pulled up to the supply voltage VDD by the P-channel transistor 712 and the P-channel transistor 714. The precharge period ends when the PRECHARGE DISABLE signal is activated, which turns off the P-channel transistor 712.

At 918, the precharge period is initiated in response to a signal initiating the memory access (see, e.g., FIG. 8 at 820). For example, the bitline precharge circuit 610 includes P-type metal-oxide-semiconductor (PMOS or P-channel) transistors 712 and 714 connected in series for precharging or pulling up the local read bitline 480 in the precharge period. The P-channel transistor 712 is coupled to the supply voltage VDD and is controlled by the PRECHARGE DISABLE signal (buffered by the inverters 716 and 718). The P-channel transistor 714 is coupled to the local read bitline 480 and controlled by the MASTER CLOCK signal (inverted by the inverter 720). To initiate a memory access, the MASTER CLOCK signal activates and starts a precharge period. The P-channel transistor 714 is turned on by the activation of the MASTER CLOCK signal, and the local read bitline 480 is precharged or pulled up to the supply voltage VDD by the P-channel transistor 712 and the P-channel transistor 714. The precharge period ends when the PRECHARGE DISABLE signal is activated, which turns off the P-channel transistor 712.

At 920, the precharge period is terminated based on a precharged level of the load circuit (see, e.g., FIG. 8 at 840). For example, to initiate a memory access, the MASTER CLOCK signal activates and starts the precharge period. The P-channel transistor 724 is turned on by the activation of the MASTER CLOCK signal, and the dummy bitline 630 at node DBL is charged or pulled up to a predetermined voltage by the P-channel transistor 722 and the P-channel transistor 724. The predetermined voltage is one that changes the state of the NOR gates 742 and 746 and leads the logic elements to activate the PRECHARGE DISABLE signal. By adjusting the predetermined voltage, the precharging of the dummy bitline 630 may be configured to be slower than the precharging of the local read bitline 480 to ensure that the PRECHARGE DISABLE signal is activated after the precharging of the local read bitline 480 (e.g., the local read bitline 480 is pulled up to the VDD level). Upon the activation of the PRECHARGE DISABLE signal, the precharge period is terminated in the following manner. The activation of the PRECHARGE DISABLE signal turns off the P-channel transistor 722 and ends the charging of the node DBL (dummy bitline 630). The activation of the PRECHARGE DISABLE signal also turns on the N-channel transistor 726 and starts to discharge the node DBL (dummy bitline 630). After the PRECHARGE DISABLE signal is activated, the DELAY MC signal (following the MASTER CLOCK signal) also activates (goes to a high level). The activation of the DELAY MC signal keeps the PRECHARGE DISABLE signal activated (at the high state) while the node DBL is being discharged by the N-channel transistors 726 and 728.

At 960, the bitline floats in the standby state (see, e.g., FIG. 8 at T₄). For example, the activation of the PRECHARGE DISABLE signal turns off the P-channel transistor 712 (via the inverters 716 and 718) and ends the precharging of the local read bitline 480. Thus, the precharge period is based on a time to charge the dummy bitline 630 (e.g., to a predetermined voltage level). The activation of the PRECHARGE DISABLE signal thus deactivates the bitline precharge circuit 610 and floats the local read bitline 480 in the standby state (e.g., after the read operation ends). Examples of these operations are described in association with FIGS. 5-8.

The specific order or hierarchy of blocks in the method of operation described above is provided merely as an example. Based upon design preferences, the specific order or hierarchy of blocks in the method of operation may be re-arranged, amended, and/or modified. The accompanying method claims include various limitations related to a method of operation, but the recited limitations are not meant to be limited in any way by the specific order or hierarchy unless expressly stated in the claims.

The various aspects of this disclosure are provided to enable one of ordinary skill in the art to practice the present invention. Various modifications to exemplary embodiments presented throughout this disclosure will be readily apparent to those skilled in the art, and the concepts disclosed herein may be extended to other magnetic storage devices. Thus, the claims are not intended to be limited to the various aspects of this disclosure, but are to be accorded the full scope consistent with the language of the claims. All structural and functional equivalents to the various components of the exemplary embodiments described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112(f) unless the element is expressly recited using the phrase “means for” or, in the case of a method claim, the element is recited using the phrase “step for.”

What is claimed is:

1. A memory, comprising:
a bitline;
at least one memory cell coupled to the bitline;
a bitline precharge circuit configured to precharge the bitline for a memory access, and configured to deactivate to float the bitline in a standby state; and
a reference circuit configured to charge a load circuit to a voltage in the standby state, wherein the reference circuit is further configured to precharge the load circuit to a second voltage for the memory access in a precharge period, and the precharge period is based on a charging time of the load circuit,
wherein the bitline precharge circuit is further configured to precharge the bitline to a third voltage for the memory access in a time period based on the precharge period.

2. (canceled)

3. The memory of claim 1, wherein the load circuit comprises a dummy bitline having a substantially same or greater electrical characteristic of the bitline, and wherein the reference circuit comprises a dummy bitline precharge circuit configured to charge the dummy bitline to the voltage in the standby state.

4. (canceled)

5. (canceled)

6. The memory of claim 1, wherein the reference circuit initiates the precharge period in response to a signal initiating the memory access.

7. The memory of claim 1, wherein the reference circuit is configured to terminate the precharge period in response to an output of the reference circuit.

8. The memory of claim 7, wherein the reference circuit comprises a metal-oxide-semiconductor (MOS) transistor having a gate configured to receive a signal initiating the memory access.

9. The memory of claim 8, wherein the reference circuit further comprises a second MOS transistor having a gate coupled to the output of the reference circuit.

10. A method for operating a memory, comprising:
precharging a bitline for a memory access, wherein the bitline is coupled to at least one memory cell;
floating the bitline in a standby state;
charging a load circuit to a voltage in the standby state as a reference for precharging the bitline;
precharging the load circuit to a second voltage for the memory access in a precharge period, wherein the precharge period is based on a charging time of the load circuit; and
precharging the bitline to a third voltage for the memory access in a time period based on the precharge period.

11. (canceled)

12. The method of claim 10, wherein the load circuit comprises a dummy bitline having a substantially same or greater electrical characteristic of the bitline.

13. (canceled)

14. (canceled)

15. The method of claim 10, further comprising initiating the precharge period in response to a signal initiating the memory access.

16. The method of claim 10, further comprising terminating the precharge period based on a precharged level of the load circuit.

17. A memory, comprising:
a bitline;
storage means for storing one or more values;
bitline precharge means for precharging the bitline for a memory access and for deactivating to float the bitline in a standby state;
reference charging means for charging a load circuit to a voltage in the standby state as a reference for the bitline precharge means precharging the bitline,
wherein the reference charging means precharges the load circuit to a second voltage for the memory access in a precharge period, and
the bitline precharge means precharges the bitline to a third voltage for the memory access in a time period based on the precharge period.

18. (canceled)

19. (canceled)

20. (canceled)

21. The memory of claim 17, wherein the load circuit comprises a dummy bitline having a substantially same or greater electrical characteristic of the bitline, and wherein the reference charging means comprises a dummy bitline precharge circuit configured to charge the dummy bitline to the voltage in the standby state.

22. The memory of claim 17, wherein the reference charging means initiates the precharge period in response to a signal initiating the memory access.

23. The memory of claim 17, wherein the reference charging means is configured to terminate the precharge period in response to an output of the reference charging means.

24. The memory of claim 23, wherein the reference charging means comprises a metal-oxide-semiconductor (MOS) transistor having a gate configured to receive a signal initiating the memory access.

25. The memory of claim 24, wherein the reference charging means further comprises a second MOS transistor having a gate coupled to the output of the reference charging means.
